(19) United States
(12) Patent Application Publication
(10) Pub. No.: US 2011/0156283 A1
(43) Pub. Date: Jun. 30, 2011

(54) Use of die backside films to modulate EOL coplanarity of thin packages while providing thermal capability and laser markability of packages

(76) Inventors: Shankar Ganapathysubramanian, Phoenix, AZ (US); Leonel R. Arana, Phoenix, AZ (US); Robert L. Sankman, Phoenix, AZ (US); Wen Janet Feng, Chandler, AZ (US); Robert M. Nickerson, Chandler, AZ (US)

(21) Appl. No.: 12/655,283

(22) Filed: Dec. 28, 2009

(51) Int. Cl. H01L 23/28; H01L 21/50; H01L 21/56

(52) U.S. Cl. 257/789; 438/113; 438/127; 257/E23.116; 257/E21.502; 257/E21.499

(57) ABSTRACT

A microelectronic package comprises a die (110) having a front side (111) containing active circuitry (115) and a back side (112) opposite the front side and a film (120) on the back side of the die. The film has a thickness (121) of at least 20 micrometers, a Young's modulus of at least 10 GPa, and a post-cure glass transition temperature of at least 100° Celsius.

### FIELD OF THE INVENTION

The disclosed embodiments of the invention relate generally to microelectronic devices, and relate more particularly to films or other treatments for such devices.

### BACKGROUND OF THE INVENTION

Warpage in microelectronic packages is primarily due to a mismatch between the CTE (coefficient of thermal expansion) of the silicon used in the packaged die and the CTE of the package substrate. Perfect package flatness is ideal but in practice is difficult to achieve. Modest amounts of warpage may therefore be acceptable, or at least tolerated, provided the degree of warpage falls within a certain range, e.g., within JEDEC limits. (JEDEC stands for Joint Electron Device Engineering Council, a standards body for semiconductor technology). Acceptable warpage limits are shrinking with each technology generation, due primarily to shrinking interconnect pitches and other package parameters that are continually being scaled down in size.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a portion of a microelectronic package according to an embodiment of the invention;

FIG. 2 is a cross-sectional view of a film for use with a microelectronic package according to an embodiment of the invention;

FIG. 3 is a flowchart illustrating a method of improving warpage of a microelectronic package according to an embodiment of the invention;

FIGS. 4-7 are cross-sectional views of a semiconductor wafer (or a singulated die obtained therefrom) as well as, in some cases, additional manufacturing components, at various stages of a manufacturing process according to an embodiment of the invention; and

FIG. 8 is a flowchart illustrating a method of improving warpage of a microelectronic package according to another embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements, while similar reference numerals may, but do not necessarily, denote similar elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a microelectronic package comprises a die having a front side containing active circuitry and a back side opposite the front side and a film on the back side of the die. The film has a thickness of at least 20 micrometers, a Young's modulus of at least 20 gigapascals (GPa), and a post-cure glass transition temperature of at least 100° Celsius (C).

It was mentioned above that acceptable warpage limits are shrinking with each technology generation as device and component sizes are scaled down. Existing solutions for meeting warpage requirements include overmolding and the use of stiffeners or an integrated heat spreader (IHS) as well as less conventional ideas such as reducing die size or reverting back to lead-based or other low temperature solders for use during chip attach. Unfortunately, significantly tight package keep-out-zone (KOZ) and/or aggressive package thickness targets do not allow the use of stiffeners or an IHS to control package warpage. Additionally, overmolding, stiffener, and IHS solutions are limited by the available space on the package; certain package-on-package (PoP) and other configurations do not allow for the implementation of these conventional solutions.

Embodiments of the invention enable low warpage packages without compromising package height (thickness) or size requirements and without the need for an expensive overmold step. These and other advantages may be achieved through the use of a stiff, high-CTE film on the backside of a microelectronic die. Such a die backside film (DBF) effectively reduces the CTE of the silicon+DBF combination and provides a way to reduce the CTE mismatch between the die and substrate. The reduced CTE mismatch has been shown to provide significant reduction in package warpage. By providing an option for marking the die surface (on the DBF), embodiments of the invention also help reduce the package size (by eliminating need for die real-estate on the substrate used specifically for marking purposes).

In addition to warpage reduction and laser markability, embodiments of the invention maintain thermal conductivity suitable to enable thermal transport through the DBF, e.g., for device testing and thermal management, and provide die surface protection against defects. The same or other embodiments may provide protections against bump crack risk and inter-layer dielectric (ILD) risk due to the reduced “effective CTE” of the “silicon+DBF” system relative to bare silicon.

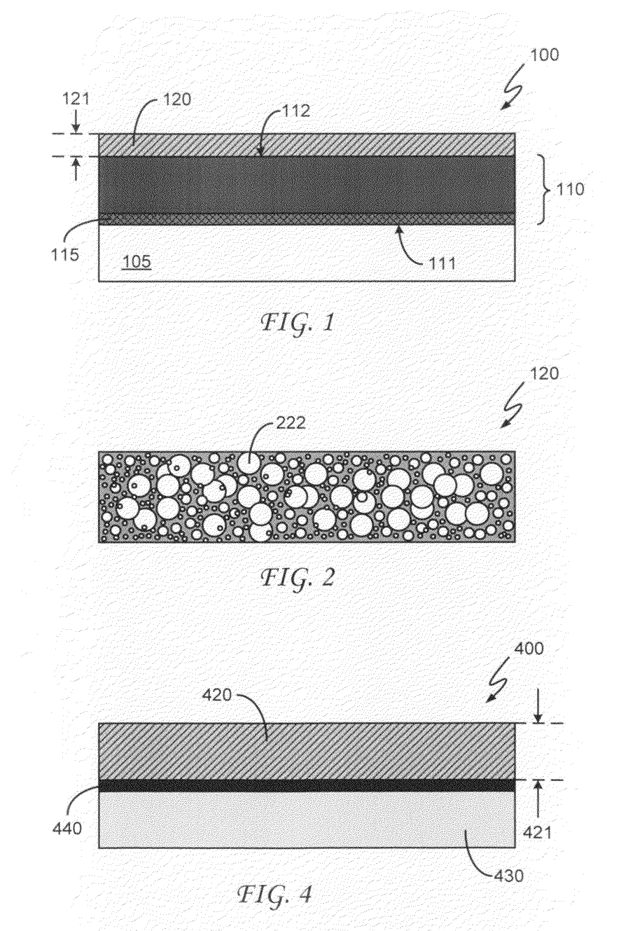

Referring now to the drawings, FIG. 1 is a cross-sectional view of a portion of a microelectronic package 100 according to an embodiment of the invention. As illustrated in FIG. 1, microelectronic package 100 comprises a package substrate 105, a die 110 over substrate 105 having a front side 111 containing active circuitry 115 and a back side 112 opposite front side 111. Microelectronic package 100 also comprises a film 120 on back side 112 of die 110. (Film 120, to use the terminology of earlier paragraphs, is a die backside film or DBF). Film 120 has a thickness 121 of at least 20 micrometers (“micrometers” is abbreviated herein as “microns” or “μm”), a Young's modulus of at least 10 GPa, and a post-cure glass transition temperature of at least 100° C. A film with these properties is thick enough and stiff enough to positively affect package flatness. Especially for thin dies (e.g., 60 μm or less), a 20 μm-thick film can provide meaningful warpage change. For thicker dies a thicker film (e.g., at least 30 μm thick) may be required.

In some embodiments, film 120 has a CTE that is no less than (and can be significantly higher than) 5 parts per million (ppm)/° C. at room temperature (taken herein to be approximately 300° Kelvin (° K)). Limiting the CTE in this way further contributes to package flatness because, when combined with the CTE of the silicon die (roughly 3 ppm/° C.), the comparatively high CTE of film 120 produces an average or effective CTE for the die/film combination that is much closer to the CTE of the package substrate than is the CTE of the die alone. Furthermore, because the relaxation response of film 120 is much slower than that of the substrate, no increase in package warpage should occur when film 120 relaxes.

The presence of film 120 slightly increases the flexural rigidity of die 110. Additionally, cure shrinkage (chemical shrinkage) of film 120 tends to warp the die in a direction opposite to that resulting from the CTE mismatch between the die (without the film) and the substrate. Both of these effects also tend to improve (i.e., reduce) the warpage of microelectronic package 100.

In certain embodiments, film 120 comprises an epoxy containing filler particles. This is depicted in FIG. 2, which is a cross-sectional view of film 120 according to an embodiment of the invention. (Note that the filler particles are not depicted in FIG. 1.) As illustrated in FIG. 2, film 120 comprises filler particles 222 which, in at least one embodiment, represent at least 50 percent by volume of film 120. In certain embodiments, filler particles 222 include particles of aluminum oxide (Al₂O₃, sometimes referred to as “alumina,” among other names) and/or particles of silicon dioxide (SiO₂, sometimes referred to as “silica”).

For many reasons, including security, branding, inventory control, and the like, it may be advantageous to have the ability to make a readable mark on the backside surface of die 110. Such marks may be made, for example, by ink printing or by laser engraving, with the latter method often being preferable because it offers higher contrast and better resolution. In order for such laser engraving to be visible, however, the engraved areas must provide sufficient contrast with the areas that have not been engraved. Accordingly, in some embodiments a pigment such as carbon black or another colorant may be added to film 120 in order to increase laser absorption and/or increase the contrast between laser-engraved and non-engraved areas on back side 112 of die 110.

As mentioned above, film 120 provides flatness benefits for a package in which it is used. There exist JEDEC standards for how flatness and warpage should be measured. The JEDEC specification for co-planarity and for flatness/warpage measurement are defined, respectively, in JESD22-B108 and JESD22-B112. In at least some embodiments, the presence of film 120 in microelectronic package 100 results in a warpage for microelectronic package 100 that is no greater than 100 micrometers. In some cases, this represents an improvement of 40 percent or more over what is achievable with existing packages.

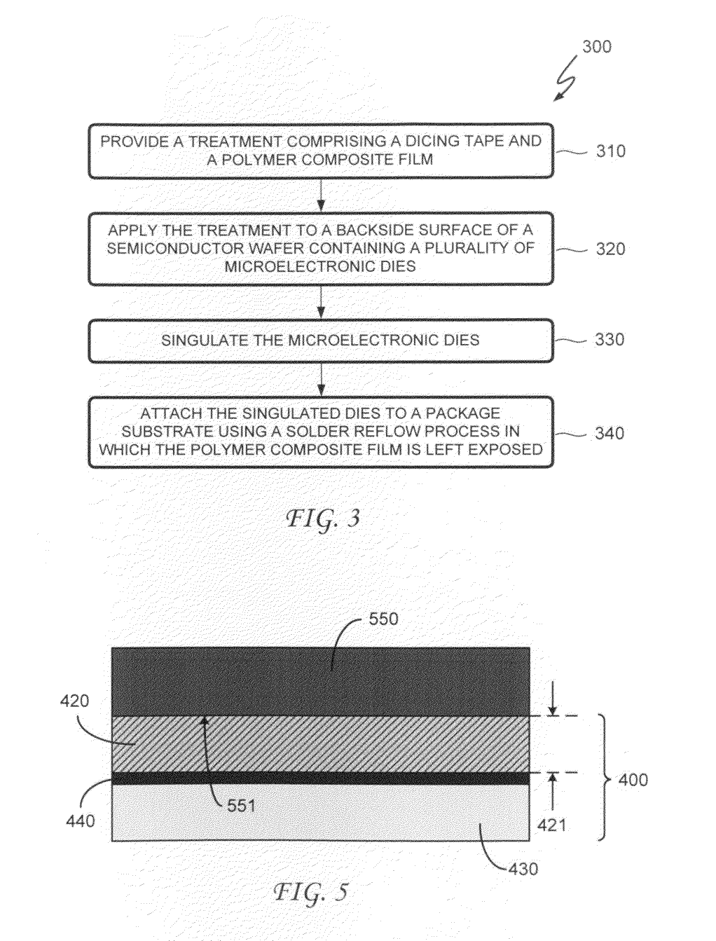

FIG. 3 is a flowchart illustrating a method 300 of improving warpage of a microelectronic package according to an embodiment of the invention. As an example, method 300 may result in an improved warpage for a package such as microelectronic package 100 that is shown in FIG. 1. Method 300 uses existing die preparation processes for DBF materials. Method 300 will be discussed with reference to FIGS. 1 and 2, introduced above, and also with reference to FIGS. 4-7, which are cross-sectional views of a semiconductor wafer (or a singulated die obtained therefrom) as well as (in some cases) additional manufacturing or other components at various stages of a manufacturing process according to an embodiment of the invention.

Some measures of flatness, including perhaps the one described above, are reported in such a way that larger measurement numbers correspond to higher warpage, i.e., lower or “worse” flatness. Therefore, it should be emphasized that references herein to “increased flatness” and the like are references to results that are closer to, not farther away from, an ideal “flatness” situation in which no warpage is present. In this context, reference to JEDEC design guide JEP95 4.17 may be instructive.

A step 310 of method 300 is to provide a treatment comprising a dicing tape and a polymer composite film. As an example, the polymer composite film can be similar to film 120 that is first shown in FIG. 1. Accordingly, the polymer composite film can have a thickness of at least 20 μm, a Young's modulus of at least 10 GPa, a post-cure glass transition temperature of at least 100° C., and a CTE that is no less than 5 ppm/° C. at room temperature. As another example, the treatment can be similar to a treatment 400 that is shown in FIG. 4 to comprise a polymer composite film 420 and a dicing tape 430, possibly connected to each other by an adhesive layer 440. As was true of film 120, polymer composite film 420 has a thickness 421 that is at least 20 μm. Dicing tape 430 may be used to enable dicing as well as die pickup according to techniques that are known in the art. Adhesive layer 440 may be required in order to provide a level of bonding between polymer composite film 420 and dicing tape 430 that is sufficient to prevent any die fly-off at dicing.

A step 320 of method 300 is to apply the treatment to a backside surface of a semiconductor wafer containing a plurality of microelectronic dies. As an example, one of the dies can be similar to die 110 that is shown in FIG. 1. FIG. 5 illustrates a wafer 550 having treatment 400 applied to a back side 551 thereof. In one embodiment, step 320 comprises laminating the treatment onto the backside surface and then partially or fully curing the polymer composite film. As an example, curing the polymer composite film can comprise exposing the polymer composite film to thermal energy such that it hardens and solidifies. In a particular embodiment, step 320 or another step comprises applying heat to the treatment during its application. Doing so may improve bonding of the polymer composite film to the silicon surface of the wafer. This heat application step may be the same as or different from the step that exposes the film to thermal radiation (if such a step is performed).

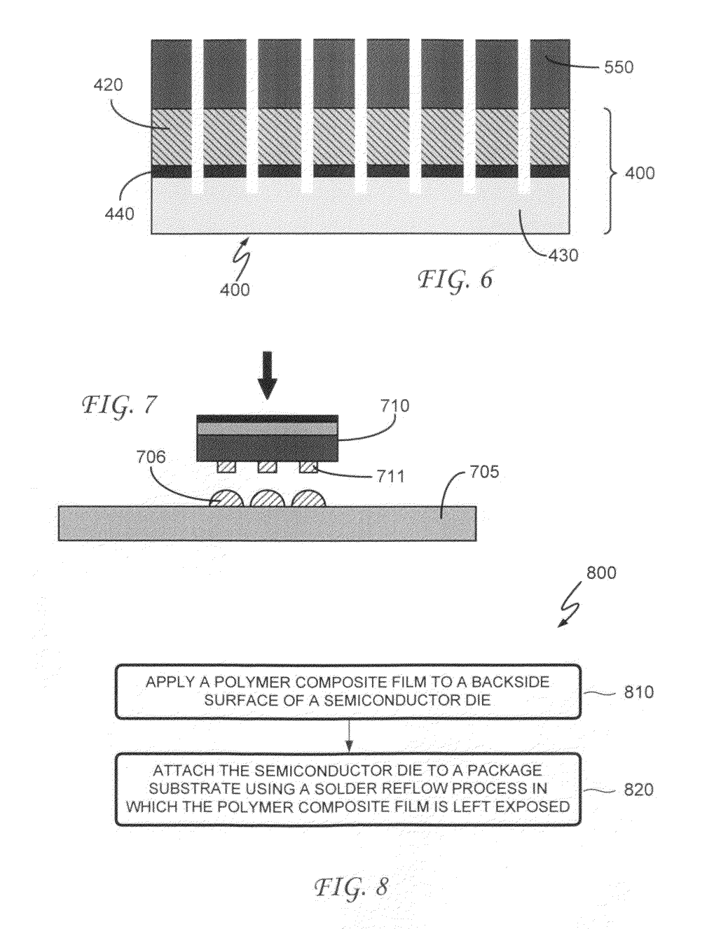

A step 330 of method 300 is to singulate the microelectronic dies. FIG. 6 depicts wafer 550 and dicing tape 430 along with polymer composite film 420 (i.e., treatment 400) after they have been cut (diced) with a saw or the like. As an example, the wafer singulation may be performed using a standard process such as wafer coat+laser scribe+saw. As shown, the saw blade simultaneously cuts through the wafer and the backside film and into dicing tape. After saw, the die are picked in standard equipment such as TRDS (tape and reel die sort). At this stage polymer composite film 420 remains attached to the die, whereas the remainder of the treatment, namely dicing tape 430 and adhesive layer 440, does not remain with the die.

A step 340 of method 300 is to attach the singulated dies to a package substrate using a solder reflow process in which the polymer composite film is left exposed. FIG. 7 is a representation of a chip attach procedure in which a singulated die 710 (similar to die 110, for example) with interconnect structures 711 is positioned over a substrate 705 having solder bumps 706 in preparation for attachment by solder reflow. As an example, the performance of steps 310-340 of method 300 may result in the creation of a microelectronic package such as microelectronic package 100 shown in FIG. 1.

FIG. 8 is a flowchart illustrating a method 800 of improving warpage of a microelectronic package according to an embodiment of the invention. As an example, method 800 may result in an improved warpage for a package such as microelectronic package 100 that is shown in FIG. 1.

A step 810 of method 800 is to apply a polymer composite film to a backside surface of a semiconductor die. In one embodiment, step 810 comprises preparing a die-shaped piece of the polymer composite film and placing the die-shaped piece of the polymer composite film onto the semiconductor die. As an example, this step can be the equivalent of step 320 of method 300 except that it is performed on a smaller scale—i.e., performed on a die level rather than on a wafer level. Accordingly, relevant parts of the above discussion of method 300 applies equally to this portion of method 800.

A step 820 of method 800 is to attach the semiconductor die to a package substrate using a solder reflow process in which the polymer composite film is left exposed. As an example, this step can be the equivalent of step 340 of method 300 that was described above.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic package and the associated film and the related structures and methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A microelectronic package comprising:
a die having a front side containing active circuitry and a back side opposite the front side; and
a film on the back side of the die,
wherein the film has:
a thickness of at least 20 micrometers;
a Young's modulus of at least 10 GPa; and
a post-cure glass transition temperature of at least 100° C.

2. The microelectronic package of claim 1 wherein:
the film has a coefficient of thermal expansion that is no less than 5 ppm/° C. at room temperature.

3. The microelectronic package of claim 1 wherein:
the film comprises an epoxy containing filler particles.

4. The microelectronic package of claim 3 wherein:
the filler particles represent at least 50 percent by volume of the film.

5. The microelectronic package of claim 3 wherein:
the filler particles include particles of aluminum oxide.

6. The microelectronic package of claim 3 wherein:
the filler particles include particles of silicon dioxide.

7. The microelectronic package of claim 1 wherein:
the film comprises a colorant.

8. The microelectronic package of claim 1 wherein:
the microelectronic package has a warpage that is no greater than 100 micrometers.

9. A method of improving warpage of a microelectronic package, the method comprising:
providing a treatment comprising a dicing tape and a polymer composite film;
applying the treatment to a backside surface of a semiconductor wafer containing a plurality of microelectronic dies;
singulating the microelectronic dies; and
attaching the singulated dies to a package substrate using a solder reflow process in which the polymer composite film is left exposed.

10. The method of claim 9 wherein:
applying the treatment comprises laminating the treatment onto the backside surface and then curing the polymer composite film.

11. The method of claim 10 wherein:
curing the polymer composite film comprises exposing the polymer composite film to thermal radiation.

12. The method of claim 9 further comprising:
applying heat to the treatment during its application.

13. The method of claim 9 wherein:
the polymer composite film has a thickness of at least 20 micrometers.

14. The method of claim 9 wherein:
the polymer composite film has a Young's modulus of at least 10 GPa.

15. The method of claim 9 wherein:
the polymer composite film has a post-cure glass transition temperature of at least 100° C.

16. A method of improving warpage of a microelectronic package, the method comprising:
applying a polymer composite film to a backside surface of a semiconductor die; and
attaching the semiconductor die to a package substrate using a solder reflow process in which the polymer composite film is left exposed.

17. The method of claim 16 wherein:
applying the polymer composite film comprises:
preparing a die-shaped piece of the polymer composite film; and
placing the die-shaped piece of the polymer composite film onto the semiconductor die.

18. The method of claim 16 wherein:
the polymer composite film has a thickness of at least 20 micrometers.

19. The method of claim 16 wherein:
the polymer composite film has a Young's modulus of at least 10 GPa.

20. The method of claim 16 wherein:
the polymer composite film has a post-cure glass transition temperature of at least 100° C.
